(19) United States
(12) Patent Application Publication
(10) Pub. No.: US 2010/0120194 A1
(43) Pub. Date: May 13, 2010

(54) METHOD OF MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/612,724

(22) Filed: Nov. 5, 2009

(30) Foreign Application Priority Data
Nov. 12, 2008 (KR) 10-2008-0112027

(51) Int. Cl. H01L 31/02; C23F 1/08

(52) U.S. Cl. 438/98; 156/345.19; 257/E31.11

(57) ABSTRACT

A method of manufacturing an image sensor includes forming an interlayer dielectric including a metal line on a semiconductor substrate, forming an image sensing part, over which a first doped layer and a second doped layer are stacked, over the interlayer dielectric, forming a via hole exposing the metal line, the via hole passing through the image sensing part and the interlayer dielectric, forming a first barrier layer and a second barrier layer over surfaces defining the via hole, forming a contact plug inside the via hole to have a first height equal to that of the first doped layer, thereby exposing the second barrier layer over the second doped layer inside the via hole, performing a wet etch process on the exposed second barrier layer to form a second barrier pattern having the same height as that of the contact plug, and performing a wet etch process on the first barrier layer to expose the second doped layer within the via hole, thereby forming a first barrier pattern.

The present application claims priority under 35 U.S.C. 119 to Korean Patent Application No. 10-2008-0112027 (filed on Nov. 12, 2008), which is hereby incorporated by reference in its entirety.

### BACKGROUND

Image sensors are semiconductor devices that convert optical images to electric signals. Image sensors are generally classified into charge coupled device (CCD) image sensors and complementary metal oxide silicon (CMOS) image sensors (CIS). The CIS includes a photodiode region for converting light signals to electrical signals, and a transistor region for processing the converted electrical signals. The photodiode region and the transistor region are horizontally arranged in a semiconductor substrate. In such a horizontal arrangement, the extent to which the optical sensing region is confined within a limited area is typically referred to as a “fill factor”.

To overcome fill factor limitations, attempts to form a photodiode using amorphous silicon (Si), or forming readout circuitry in the Si substrate using a method such as wafer-to-wafer bonding and forming a photodiode over the readout circuitry have been made (hereinafter, referred to as a “three-dimensional (3D) image sensor). The photodiode is connected with the readout circuitry through a metal line.

In wafer-to-wafer bonding, since a bonded surface of the wafer is non-uniform, a bonding force may be reduced. That is, since the metal line for connecting the photodiode to the circuitry is exposed to a surface of an interlayer dielectric, the interlayer dielectric has a non-uniform surface profile. Thus, the bonding force between the interlayer dielectric and the photodiode formed on the interlayer dielectric may be reduced.

### SUMMARY

Embodiments provide a method of manufacturing an image sensor in which a vertical-type image sensing part is adopted to improve, inter alia, a physical and electrical contact force between the image sensing part and a substrate including readout circuitry.

In embodiments, a method of manufacturing an image sensor includes: forming an interlayer dielectric including a metal line over a semiconductor substrate, forming an image sensing part, over which a first doped layer and a second doped layer are stacked, over the interlayer dielectric, forming a via hole exposing the metal line, the via hole passing through the image sensing part and the interlayer dielectric, forming a first barrier layer and a second barrier layer over surfaces defining the via hole, forming a contact plug inside the via hole to have a first height equal to that of the first doped layer, thereby exposing the second barrier layer over the second doped layer inside the via hole, performing a wet etch process on the exposed second barrier layer to form a second barrier pattern having the same height as that of the contact plug, and performing a wet etch process on the first barrier layer to expose the second doped layer within the via hole, thereby forming a first barrier pattern.

### DRAWINGS

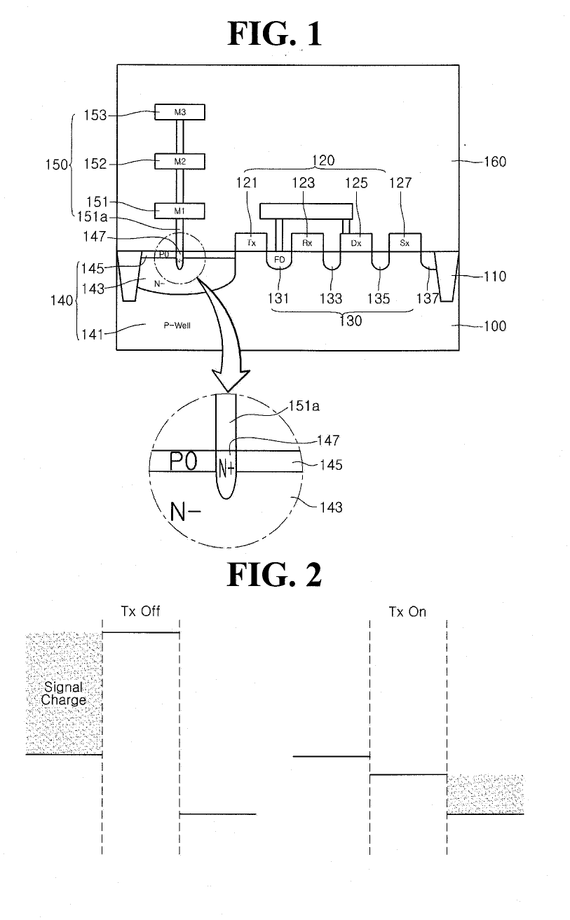

Example FIGS. 1 to 9 are cross-sectional view illustrating a process of manufacturing an image sensor according to embodiments.

### DESCRIPTION

Hereinafter, a method of manufacturing an image sensor will be described in detail with reference to the accompanying drawings. Embodiments are not limited to a complementary metal oxide silicon (CMOS) image sensor (CIS). For example, embodiments may be applicable to all image sensors in which a photodiode is required such as a charge coupled device (CCD) image sensor.

Hereinafter, a method of manufacturing an image sensor will be described with reference to example FIGS. 1 to 9. Referring to example FIG. 1, a metal line 150 and an interlayer dielectric 160 may be formed over a semiconductor substrate 100 including readout circuitry 120.

The semiconductor substrate 100 may include a single crystalline or polycrystalline silicon substrate. Also, the semiconductor substrate 100 may include a substrate doped with p-type impurities and/or n-type impurities. A device isolation layer 110 may be formed in the semiconductor substrate 100 to define an active region. The readout circuitry 120 including at least one transistor may be formed in the active region. For example, the readout circuitry 120 may include a transfer transistor (Tx) 121, a reset transistor (Rx) 123, a drive transistor (Dx) 125, and a select transistor (Sx) 127. Thereafter, an ion implantation region 130 including a floating diffusion region (FD) 131 and source/drain regions 133, 135, and 137 for each transistor may be formed. Also, the readout circuitry 120 may be applicable to a 3Tr or 5Tr structure.

The forming of the readout circuitry 120 in the semiconductor substrate 100 may include forming an electrical junction region 140 in the semiconductor substrate 100 and forming a first conductivity type connection region 147 connected to the metal line 150 over the electrical junction region 140. For example, the electrical junction region 140 may be a PN junction 140, but is not limited thereto. For example, the electrical junction region 140 may include a first conductivity type ion implantation layer 143 formed over a second conductivity type well 141 or a second conductivity type epitaxial layer, and a second conductivity type ion implantation layer 145 formed over the first conductivity type ion implantation layer 143. As an example, the PN junction 140 may include P0(145)/N−(143)/P−(141) junction as shown in example FIG. 1, but is not limited thereto. Also, the semiconductor substrate 100 may be doped with a second conductivity type impurity, but is not limited thereto.

According to embodiments, it may be possible to fully dump photo charges by designing the image sensor such that a potential difference exists between source and drain formed in both ends of the Tx 121. As a result, the photo charges generated in the photodiode may be dumped into the floating diffusion region to enhance the sensitivity of an output image. That is, since the electrical junction region 140 may be formed in the semiconductor substrate 100 including the first readout circuitry 120 to generate the potential difference between the source and the drain formed in both ends of the Tx 121, it may be possible to fully dump the photo charges.

In embodiments, unlike the FD 131 node that is an N+ junction, the electrical junction region 140, i.e., the P/N/P junction 140 may not fully receive an applied voltage, but may be pinched off at a constant voltage. This voltage is called a “pinning voltage”, which depends on doping concentrations of P0 145 and N− junction 143.

Particularly, electrons generated in the photodiode may be moved to the P/N/P junction 140, and when the Tx 121 is turned on, the electrons may be transferred to the FD 131 node and converted to a voltage. The reason that 140 may be formed as a P0/N−/Pwell junction, but Tx 121 may be a N+/Pwell junction formed in the semiconductor substrate 100, i.e., Si-Sub, is because during a 4-Tr APS Reset operation, a positive (+) voltage is applied to N− junction 143 of the

P0/N−/Pwell junction, and a ground voltage is applied to P0 145 and Pwell 141, to allow P0/N−/Pwell double junction to be pinched off under a voltage of more than a constant voltage as shown in a BJT structure. This is called “Pinning voltage”.

Thus, as shown in example FIGS. 1 and 2, a potential difference between the source and the drain formed in both ends of the Tx 121 is generated, and thus when the transfer transistor (Tx) is turned on/off, the photo charges may be fully dumped through Tx 121 in an N-well to prevent a charge sharing phenomenon from occurring. Accordingly, unlike related image sensor technology where the photodiode is simply connected to N+ junction, embodiments may prevent the saturation and sensitivity from being lowered.

Next, according to embodiments, the first conductivity type connection region 147 may be formed between the photodiode and the readout circuitry 120 to help smooth movement of the photo charges, thereby minimizing a source of dark current and preventing the saturation and sensitivity from being lowered. For those purposes, an N+ doped region 147 may be formed in a surface of P0/N−/P− junction 140 as the first conductivity type connection region 147 for an ohmic contact. The N+ doped region 147 may be formed so as to penetrate the P0 145 and contact the N− junction 143. To minimize possibility that the first conductivity type connection region 147 acts as a leakage source, a width of the first conductivity type connection region 147 may be minimized.

For this purpose, in embodiments, a first metal contact 151 a may be first etched, and then a plug implant may be performed, but embodiments are not limited thereto. For example, an ion implantation pattern may be formed, and then the first conductivity type connection region 147 may be formed using the ion implantation pattern as an ion implantation mask. That is, the N+ doping region may be locally performed on only the contact formation portion to minimize a dark signal and smoothly form the ohmic contact. As in the related art, in cases where an entire source region of Tx 121 is doped with the N+ impurities, a dark signal may increase due to Si surface dangling bond.

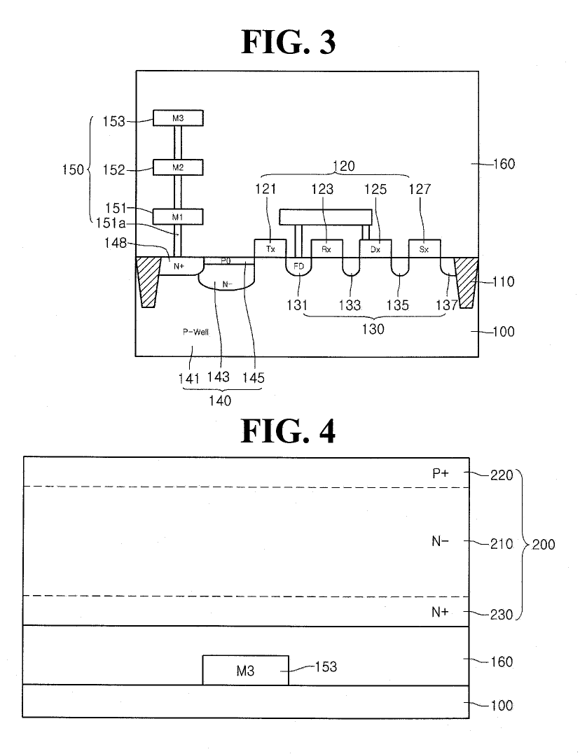

Example FIG. 3 is a view illustrating another structure of a readout circuitry. As shown in example FIG. 3, a first conductivity type connection region 148 may be formed in a side of the electrical junction region 140.

Referring to example FIG. 3, the N+ connection region 148 for an ohmic contact may be formed in the P0/N−/P− junction 140. At this time, the N+ connection region 148 and the first metal contact (M1C) 151a may act as a leakage source. This is because in operation, a reverse bias may be applied to the P0/N−/P− junction 140 to generate an electric field (EF) in a surface of the Si substrate. Thus, a crystal defect generated in the EF during the formation of the contact may act as a leakage source.

Also, in cases where the N+connection region 148 is formed over a surface of the P0/N−/P− junction 140, an additional electric field may be generated by the N+/P0 junction 148/145, which may also act as the leakage source. That is, embodiments provide a layout in which a doping process is not performed into the P0 layer, a first contact plug is formed in an active region including the N+ connection region 148, and the first contact plug is connected to the N− junction 143. As a result, the electric field may not be generated in the surface of the semiconductor substrate 100, reducing the dark current of the 3-D integrated CIS.

Referring again to example FIG. 1, the interlayer dielectric 160 and the metal line 150 may be formed over the semiconductor substrate 100. The metal line 150 may include the first metal contact 151a, a first metal (M1) 151, a second metal (M2) 152, and a third metal (M3) 153, but embodiments are not limited thereto. In embodiments, after the M3 153 is formed, a dielectric may be deposited such that the M3 153 is not exposed. Then, a planarization process may be performed to form the interlayer dielectric 160. Thus, a surface of the interlayer dielectric 160 having a uniform surface profile may be exposed to the semiconductor substrate 100.

Referring to example FIG. 4, an image sensing part 200 may be formed over the interlayer dielectric 160. The image sensing part 200 may have a PN junction diode structure including a first doped layer (N−) 210 and a second doped layer (P+) 220. Also, in the image sensing part 200, an ohmic contact layer (N+) 230 may be formed below the first doped layer 210. Since the M3 153 and of the metal line 150 illustrated in example FIG. 4 and the interlayer dielectric 160 correspond to portions of the metal line 150 illustrated in example FIG. 1 and the interlayer dielectric 160, the readout circuitry 120 and a portion of the metal line 150 will be omitted for convenience of description.

The image sensing part 200 may have a structure in which N-type impurities (N−) and P-type impurities (P+) may be sequentially ion-implanted into a p-type carrier substrate with a crystalline structure to form a stacked structure of the first doped layer 210 and the second doped layer 220. In addition, high-concentration n-type impurities (N+) may be ion-implanted into a bottom surface of the first doped layer 210 to form the ohmic contact layer 230. The ohmic contact layer 230 may reduce a contact resistance between the image sensing part 200 and the metal line 150. In embodiments, the first doped layer 210 may be wider than the second doped layer 220. Thus, a depletion region may be expanded to increase the production of photoelectrons.

Next, the ohmic contact layer 230 of the carrier substrate may be disposed over the interlayer dielectric 160. Then, a bonding process may be performed to couple the semiconductor substrate 100 to the carrier substrate. Thereafter, the carrier substrate in which a hydrogen layer is formed to expose the image sensing part 200 bonded on the interlayer dielectric 160 may be removed by a cleaving process to expose the second doped layer 220. For example, the image sensing part 200 may have a height of about 1.0 μm to about 1.5 μm. That is, since the semiconductor substrate 100 including the readout circuitry 120 and the image sensing part 200 are formed using the wafer-to-wafer bonding, defects may be prevented from occurring.

Also, the image sensing part 200 may be formed over the readout circuitry 120 to increase a fill factor. In addition, since the image sensing part 200 is bonded to the interlayer dielectric 160 which has a uniform surface profile, equalization of physical bonding forces may be improved. Although the image sensing part 200 may have a PN junction, embodiments are not limited thereto. For example, the image sensing part 200 may have a PIN junction.

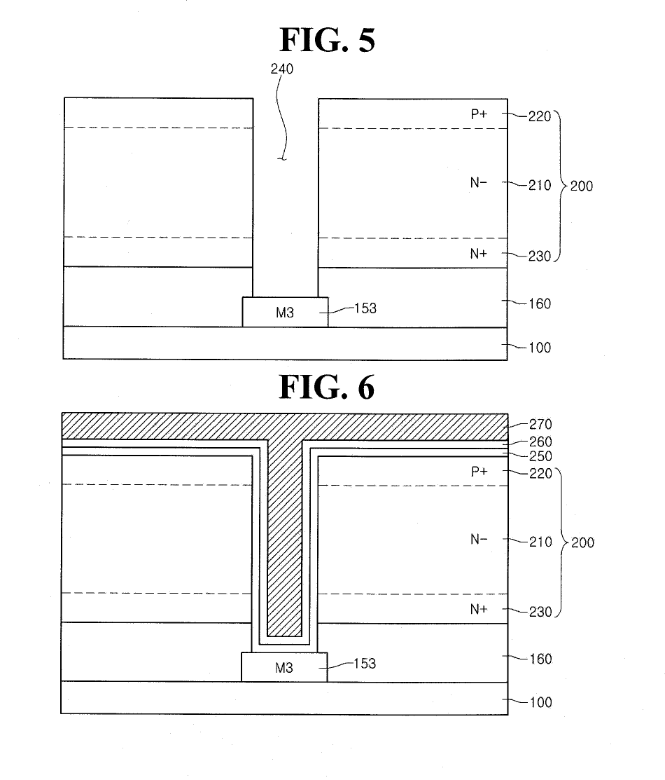

Referring to example FIG. 5, a via hole 240 passing through the image sensing part 200 and the interlayer dielectric 160 may be formed. The via hole 240 may be a deep via hole. The via hole 240 may expose a surface of the M3 153 within the interlayer dielectric 160.

A hard mask and a photoresist pattern may be formed over the image sensing part 200, and then the image sensing part 200 and the interlayer dielectric 160 may be selectively etched to form the via hole 240. At this time, a surface of the image sensing part 200 corresponding to the M3 153 may be exposed through opening of the hard mask and the photoresist pattern. Thereafter, the photoresist pattern may be removed using an ashing process. The hard mask may remain on the image sensing part 200. In embodiments, the hard mask may also be removed.

Referring to example FIG. 6, a first barrier layer 250, a second barrier layer 260, and a metal layer 270 may be formed over the image sensing part 200 including the via hole 240. For example, the first barrier layer 250 may include a Ti layer, and the second barrier layer 260 may include a TiN layer. Also, the metal layer 270 may be formed of a metal such as tungsten W, copper Cu, and aluminium Al. In embodiments, the metal layer 270 may be formed of W.

The first and second barrier layers 250 and 260 prevent the M3 153, exposed by the via hole 240, from being oxidized and protect the interlayer dielectric 160. The first and second barrier layers 250 and 260 may be formed in a thin film shape along a height difference between the image sensing part 200 and the via hole 240. A metal material may be deposited to gap-fill the via hole 240 in which the first and second barrier layers 250 and 260 are formed, thereby forming the metal layer 270.

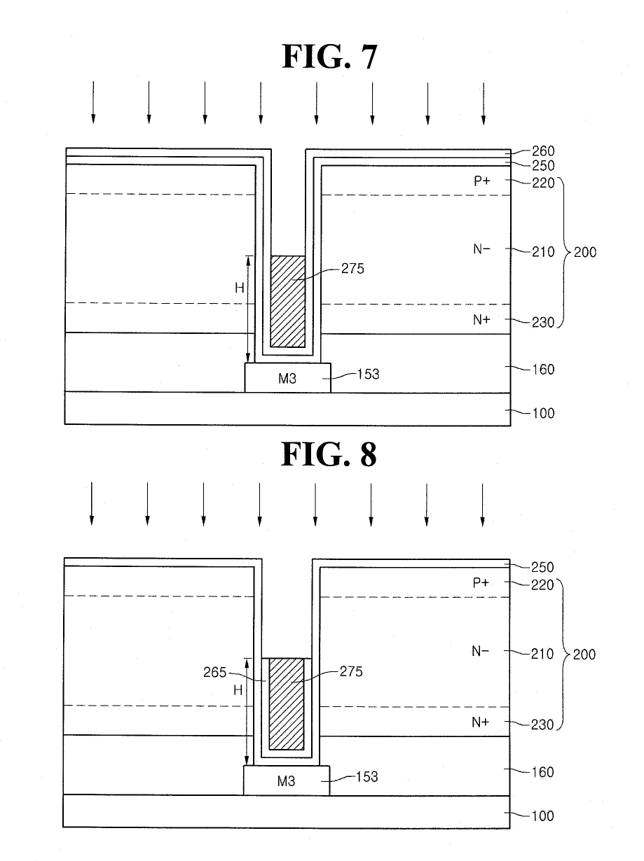

Referring to example FIG. 7, the metal layer 270 may be etched by a primary etch process to form a contact plug 275 within the via hole 240. The primary etch process may be performed to selectively remove only the tungsten by performing an etch back process over the metal layer 270.

For example, the contact plug 275 may be formed by an etch process using SFₓ gas (1<x<6) and Ar gas as etch gases. At this time, since the SFₓ gas does not etch the Ti layer and the TiN layer and only deforms surfaces of the Ti and TiN layers, the SFₓ gas may act as a defect source due to plasma damage. Thus, an additional process for removing the first and second barrier layers 250 and 260 may be required.

The contact plug 275 formed by the primary etch process may have a height corresponding to that of the first doped layer 210. That is, the contact plug 275 may expose the second barrier layer 260 within the via hole 240 corresponding to the second doped layer 220. The contact plug 275 may expose the second doped layer 220 and the second barrier layer 260 corresponding to an upper region of the first doped layer 210 contacting the second doped layer 220 with respect to a sidewall of the via hole 240. For example, the contact plug 275 may have a first height H with respect to the M3 153.

Referring to example FIG. 8, a secondary etch process may be performed on the second barrier layer 260 to form a second barrier pattern 266. A wet etch process using H₂O₂ as an etch solution may be performed to form the second barrier pattern 255. Since the H₂O₂ may effectively remove only the TiN layer without damaging the contact plug 275, only the second barrier layer 260 may be selectively removed.

Specifically, in the secondary etch process, the H₂O₂ of about 20% to about 25% may be diluted with deionized (DI) water. Also, for example, the H₂O₂ and the DI water may be diluted at a concentration ratio of about 30:1 to about 50:1. Thus, when the secondary etch process is performed at a temperature of about 45° C. to about 60° C. for about 60 seconds to about 300 seconds using the diluted H₂O₂, only the second barrier layer 260 formed of TiN may be removed to form the second barrier pattern 255. Specifically, the concentration and temperature of the H₂O₂ may be controlled during the secondary etch process to prevent the first barrier layer 250 and the contact plug 275 from being damaged. Also, since the contact plug 275 may be used as a protective mask during the secondary etch process, only the second barrier layer 260 exposed by the contact plug 275 may be removed.

As described above, the secondary etch process may be performed to selectively etch only the second barrier layer 260 and remove only the second barrier layer 260 exposed by the contact plug 275, thereby forming the second barrier pattern 255. Thus, the second barrier pattern 255 may have the first height H equal to that of the contact plug 275. As a result, the first barrier layer 250 within the via hole 240 may be exposed.

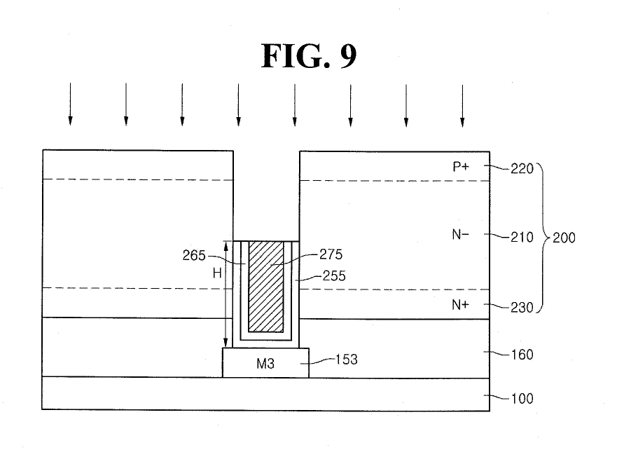

Referring to example FIG. 9, a tertiary etch process is performed on the first barrier layer 250 to form a first barrier pattern 265.

A wet etch process using tetra methylammonium hydroxide (TMH) and H₂O₂ as an etch solution may be performed to form the first barrier pattern 265. The THM and H₂O₂ are mixed to have a specific etch rate with respect to the contact plug 275. Here, since the Ti layer that is the first barrier layer 250 has an etch rate greater than the contact plug 275 formed of W, the first barrier layer 250 may be selectively etched.

Specifically, in the tertiary etch process, the THM and the H₂O₂ chemicals are mixed at a ratio of about 1:25 to about 1:35, and then, Di water is added to the mixture of the THM and the H₂O₂ chemicals to form a mixture of TMH:H₂O₂:DI water having a ratio of about 1:25:10 to about 1:35:10. Thereafter, when the tertiary etch process is performed for about 300 seconds to about 600 seconds using the resultant mixture of TMH:H₂O₂:DI water, only the first barrier layer 250 may be selectively removed to form the first barrier pattern 265. Also, since the contact plug 275 and the second barrier pattern 255 may be used as protective masks during the tertiary etch process, only the exposed second barrier layer 260 may be removed.

As described above, only the first barrier layer 250 may be selectively etched by the tertiary etch process to remove only the first barrier layer 250 exposed by the contact plug 275 and the second barrier pattern 255, thereby forming the first barrier pattern 265. Thus, the first barrier pattern 265 may have the first height H equal to those of the second barrier pattern 255 and the contact plug 275. As a result, a sidewall of the via hole 240 may be exposed.

That is, the first and second barrier patterns 265 and 255 and the contact plug 275 may be electrically connected to only the first doped layer 210 and the M3 153 to transmit the photo charges generated in the image sensing part 200 to the readout circuitry 120. Also, since the first and second barrier patterns 265 and 255 and the contact plug 275 may be electrically connected to only the first doped layer 210 within the via hole 240, the first doped layer 210 may be electrically isolated from the second doped layer 220 to prevent the device from malfunctioning.

In addition, since the primary etch process is performed on the contact plug 275, and then, the secondary and tertiary etch processes are performed using the chemicals to form the first and second barrier patterns 265 and 255, the plasma damage may not occur, thereby improving a dark current characteristic of the image sensing part 200. Additionally, an upper electrode, a color filter, and a micro lens may be formed over the image sensing part 200.

As described above, the via hole 240 may be formed in the image sensing part 200 and the interlayer dielectric 150 to expose the M3 153. After the first and second barrier layers 250 and 260 and the metal layer 270 is formed over the via hole 240, the etch back process for the PN junction may be performed on the metal layer 270. As a result, the first and second barrier layers 250 and 260 remain over an upper portion and sidewall of the image sensing part 200. The etch process is performed to selectively remove the first and second barrier layers 250 and 260 remaining over the sidewall of the via hole 240. Specifically, since plasma damage does not occur in the etching process, the dark current may not be generated to improve efficiency of the device.

In a method of manufacturing the image sensor according to embodiments, the readout circuitry and the image sensing part may be vertically integrated to reach nearly 100% fill factor. Also, since the image sensing part is bonded to the surface of the interlayer dielectric of the substrate, a physical and electrical contact force between the image sensing part and the substrate may be superior, thereby improving the quality of the image sensor.

Also, since the deep via hole passing through the image sensing part is formed, and the first and second barrier patterns and the contact plug connected to the metal line and the first doped layer of the image sensing part are formed inside the deep via hole, electrons within the image sensing part may be transmitted to the readout circuitry to normally operate a signal output of the photodiode.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an interlayer dielectric including a metal line over a semiconductor substrate;
forming an image sensing part, over which a first doped layer and a second doped layer are stacked, over the interlayer dielectric;
forming a via hole exposing the metal line, the via hole passing through the image sensing part and the interlayer dielectric;
forming a first barrier layer and a second barrier layer over surfaces defining the via hole;
forming a contact plug inside the via hole to have a first height equal to that of the first doped layer, thereby exposing the second barrier layer over the second doped layer inside the via hole;
performing a wet etch process on the exposed second barrier layer to form a second barrier pattern having the same height as that of the contact plug; and
performing a wet etch process on the first barrier layer to expose the second doped layer within the via hole, thereby forming a first barrier pattern.

2. The method of claim 1, wherein the forming of the contact plug includes:
forming a metal layer to gap-fill the inside of the via hole in which the first and second barrier layers are formed; and
performing an etch back process on the metal layer to selectively remove the metal layer such that the metal layer has the first height corresponding to that of the first doped layer.

3. The method of claim 2, wherein the etch back process for forming the contact plug is performed using SFₓ gas, wherein x is a whole number between 1 and 6, and Ar gas.

4. The method according to claim 1, wherein the exposed second barrier layer is etched with a mixture of H₂O₂ and deionized water, using the contact plug as a protective mask, to form the second barrier pattern.

5. The method of claim 4, wherein the H₂O₂ and the deionized water are mixed at a concentration ratio of about 30:1 to about 50:1.

6. The method of claim 4, wherein the etch process for forming the second barrier pattern is performed using the mixture of the H₂O₂ and the deionized water for about 60 seconds to about 300 seconds.

7. The method of claim 1, wherein the first barrier layer is etched using the contact plug and the second barrier pattern as protective masks and using a mixture of tetra methylammonium hydroxide, H₂O₂ and deionized water to form the first barrier pattern.

8. The method of claim 7, wherein the tetra methylammonium hydroxide, the H₂O₂, and the deionized water are mixed at a concentration ratio of about 1:25:10 to about 1:35:10.

9. The method of claim 7, wherein the etch process for forming the first barrier pattern is performed using the mixture of the tetra methylammonium hydroxide, the H₂O₂, and the deionized water for about 300 seconds to about 600 seconds.

10. The method of claim 1, wherein the contact plug is formed of tungsten.

11. The method of claim 1, wherein the first barrier layer includes a Ti layer.

12. The method of claim 1, wherein the second barrier layer includes a TiN layer.

13. An apparatus configured to:
form an interlayer dielectric including a metal line over a semiconductor substrate;
form an image sensing part, over which a first doped layer and a second doped layer are stacked, over the interlayer dielectric;
form a via hole exposing the metal line, the via hole passing through the image sensing part and the interlayer dielectric;
form a first barrier layer and a second barrier layer over surfaces defining the via hole;
form a contact plug inside the via hole to have a first height equal to that of the first doped layer, thereby exposing the second barrier layer over the second doped layer inside the via hole;
perform a wet etch process on the exposed second barrier layer to form a second barrier pattern having the same height as that of the contact plug; and
perform a wet etch process on the first barrier layer to expose the second doped layer within the via hole, thereby forming a first barrier pattern.

14. The apparatus of claim 13, configured to:
form a metal layer to gap-fill the inside of the via hole in which the first and second barrier layers are formed; and
perform an etch back process on the metal layer to selectively remove the metal layer such that the metal layer has the first height corresponding to that of the first doped layer, thereby forming the contact plug.

15. The apparatus of claim 14, configured to use SFₓ gas, wherein x is a whole number between one and six, and Ar gas, in the etch back process for to form the contact plug.

16. The apparatus according to claim 13, configured to form the second barrier pattern by etching the exposed second barrier layer with a mixture of H₂O₂ and deionized water, using the contact plug as a protective mask.

17. The apparatus of claim 16, wherein the H₂O₂ and the deionized water are mixed at a concentration ratio of about 30:1 to about 50:1.

18. The apparatus of claim 16, configured to perform the etch process for forming the second barrier pattern using the mixture of the H₂O₂ and the deionized water for about 60 seconds to about 300 seconds.

19. The apparatus of claim 13, configured to etch the first barrier layer using the contact plug and the second barrier pattern as protective masks and using a mixture of tetra methylammonium hydroxide, H₂O₂ and deionized water to form the first barrier pattern.

20. The apparatus of claim 19, configured to use a mixture of tetra methylammonium hydroxide, the H₂O₂, and the deionized water at a concentration ratio of about 1:25:10 to about 1:35:10.
